(19) United States
(12) Patent Application Publication
(10) Pub. No.: US 2019/0385956 A1
(43) Pub. Date: Dec. 19, 2019

(54) SEMICONDUCTOR CHIP

(71) Applicant: Samsung Electro-Mechanics Co., Ltd., Suwon-si (KR)

(72) Inventors: Ung Hui SHIN, Suwon-si (KR); Jong Rip KIM, Suwon-si (KR); Doo Hwan LEE, Suwon-si (KR); Sung Hwan CHO, Suwon-si (KR)

(73) Assignee: Samsung Electro-Mechanics Co., Ltd., Suwon-si (KR)

(21) Appl. No.: 16/555,498

(22) Filed: Aug. 29, 2019

Related U.S. Application Data
(62) Division of application No. 14/992,653, filed on Jan. 11, 2016.

(30) Foreign Application Priority Data
Mar. 19, 2015 (KR) 10-2015-0037959

(51) Int. Cl. H01L 23/00

(52) U.S. Cl. CPC H01L 23/562; H01L 23/3736

(57) ABSTRACT

A semiconductor chip includes: a body; holes disposed in a first surface of the body; and a warpage preventing member including filling members disposed in the holes.

### CROSS-REFERENCE TO RELATED APPLICATION(S)

This application is a divisional application of U.S. application Ser. No. 14/992,653 filed on Jan. 11, 2016, which claims the benefit of Korean Patent Application No. 10-2015-0037959 filed on Mar. 19, 2015 in the Korean Intellectual Property Office, the entire disclosure of which is incorporated herein by reference for all purposes.

### BACKGROUND

### 1. Field

The following description relates to a semiconductor chip, and more particularly, to a semiconductor chip that is resistant to warpage and has excellent heat dissipation characteristics.

### 2. Description of Related Art

Recently, in accordance with the trend towards lightness, miniaturization, increases in operating speeds, multifunctionalization, improvements in performance, and the like, of electronic products, semiconductor chips mounted in such electronic products have been required to have high degrees of reliability. Therefore, to protect semiconductor chips from various external environmental factors such as dust and moisture, and from damage due to factors such as high electrical loads, and the like, in order to optimize and significantly improve the electrical performance of semiconductor chips, demand has gradually increased for a semiconductor package in which terminals for inputting signals to and outputting signals from a main board are formed using a lead frame, a printed circuit board, or the like, that is molded using a sealant.

Generally, semiconductor packages have been provided as semiconductor modules in which semiconductor chips are mounted two-dimensionally on at least one surface of a package board, such as the printed circuit board, through surface mount technology (SMT). When warpage or deformation is generated in the semiconductor chip, it may be difficult or impossible to mount the semiconductor chip on the package board. Particularly, in a case in which the semiconductor chip is mounted on the package board through a ball grid array (BGA) installed on the other surface thereof, a defect in which a certain amount of solder balls are not connected to the package board may occur.

Therefore, a semiconductor chip with increased warpage resistance is desired.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a semiconductor chip includes: a body; holes disposed in a first surface of the body; and a warpage preventing member including filling members disposed in the holes.

The warpage preventing member may further include a surface member covering the first surface of the body.

The filling members and the surface member may be formed as a single integrated structure.

The first surface of the body may oppose a second, mounting surface of the body.

The warpage preventing member may have a coefficient of thermal expansion that is greater than a coefficient of thermal expansion of the body.

The warpage preventing member may have thermal conductivity that is greater than a thermal conductivity of the body.

The warpage preventing member may be formed of a metal or a resin.

The warpage preventing member may be formed of the metal and have a Young's modulus that is greater than a Young's Modulus of the body.

The warpage preventing member may be formed of the resin and have a coefficient of thermal expansion that is greater than a coefficient of thermal expansion of a solder resist layer provided on a second, mounting surface of the body.

Each of the holes and each of the filling members may extend only partially through the body.

According to another general aspect, a semiconductor chip includes: a body including an upper surface and a lower surface; holes penetrating through the upper surface and the lower surface; a solder resist layer disposed on the upper surface or the lower surface; and a warpage preventing member including filling members disposed in the holes, and a surface member disposed on one of the upper surface and the lower surface opposing the other of the upper surface and the lower surface on which the solder resist layer is disposed.

The filling members and the surface member may be formed as a single integrated structure.

The warpage preventing member may have a coefficient of thermal expansion that is greater than a thermal coefficient of expansion of the body.

The warpage preventing member may have thermal conductivity that is greater than a thermal conductivity of the body.

The warpage preventing member may be formed of a metal or a resin.

The warpage preventing member may be formed of the metal and have a Young's modulus that is greater than a Young's modulus of the body.

The warpage preventing member may be formed of the resin and have a coefficient of thermal expansion that is greater than a thermal coefficient of expansion of the solder resist layer.

Each of the holes and each of the filling members may extend entirely through the body.

Other features and aspects will be apparent from the following detailed description, the drawings, and the claims.

### BRIEF DESCRIPTION OF THE DRAWINGS

FIG. 1 is a cross-sectional view of a semiconductor chip according to an embodiment.

FIG. 2A is a view illustrating a direction of force applied to a body of the semiconductor chip of FIG. 1 during grinding.

FIG. 2B is a view illustrating a warpage phenomenon occurring in the body after grinding.

FIG. 3 is a view illustrating a movement path of heat generated in the semiconductor chip of FIG. 1.

FIG. 4 is a cross-sectional view of a semiconductor chip according to another embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

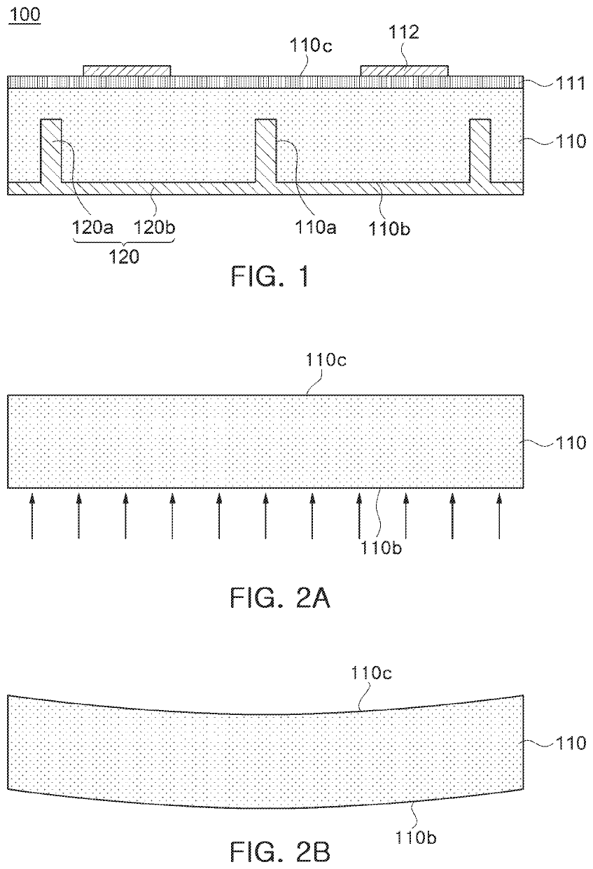

FIG. 1 is a cross-sectional view of a semiconductor chip 100 according to an embodiment. Referring to FIG. 1, the semiconductor chip 100 includes a body 110, holes 110a formed in a first, lower surface 110b of the body 110, and a warpage preventing member 120.

The body 110 may be a substrate formed of silicon, which is a base material of a chip. Although not illustrated, various devices for processing and storing data, for example, a transistor, a diode, a resistor, a condenser, and the like, may be integrated in the body 110, and a circuit for electrically connecting these devices to each other may be designed in the body 110.

In addition, a solder resist layer 111 is disposed on the a second, upper surface 110c of the body 110 that opposes the first surface 110b so as to protect the devices in the body 110 from an external environment, prevent solder from hardening in an undesired position and prevent a solder bridge from being formed during soldering. Additionally, connection electrodes 112 for transferring signals externally and having a land shape (e.g., substantially flat, planar) are formed on the solder resist layer 110.

When the semiconductor chip 100 is mounted on a package board (not shown), the connection electrodes 112 may be electrically connected to circuits of the package board through a ball grid array (BGA) scheme using a solder ball or a wire bonding scheme. In this case, the second surface 110c of the body 110 on which the connection electrodes 112 are formed may be disposed to face the package board. Therefore, in FIG. 1, the second surface 110c of the body 110 may be provided as a mounting surface with respect to the package board.

The body 110 may be prepared in the form of an individual chip having an approximately rectangular parallelepiped shape after being cut or may be prepared in the form of a wafer before being cut. After various devices are integrated in the body 110, grinding is performed on the first surface 110b of the body 110, that is, a surface of the body 110 opposing the surface of the body 110 on which the solder resist layer 111 is formed, in order to adjust a final thickness.

FIG. 2A is a view illustrating a direction of force applied to the body 110 during grinding. FIG. 2B is a view illustrating a warpage phenomenon occurring in the body 110 after grinding.

Referring to FIG. 2A, stress is continuously applied to the body 110 in a direction in which the body 110 is ground (a direction of the arrows in FIG. 2A) during grinding. As a result, when grinding ends, residual stress accumulated in the body 110 is removed at once, and force acts on the body 110 as a reaction to the removal of the residual stress such that warpage is generated in the body 110, thereby causing the body 110 to have a curved shape.

The warpage preventing member 120 is provided as a member for preventing the above-mentioned warpage phenomenon. In detail, the holes 110a are formed in the first surface 110b of the body 110, that is, the ground surface of the body 110, and the warpage preventing member 120 includes filling members 120a formed in the holes 110a, as a first component. The holes 110a and the filling members 120a may be formed to have a predetermined depth without completely penetrating through the body 110, and may be formed in a dummy region of the body 110 so as not to penetrate through an integrated circuit of the body 110.

The warpage preventing member 120 is formed by filling the holes 110a with a material of the warpage preventing member 120. The material of the warpage preventing member 120 covers the first surface 110b of the body 110 in which the holes 110a are formed. More specifically, the warpage preventing member 120 includes a surface member 120b extending externally from the holes 110a and formed on the surface of the body 110, as a second component, together with the filling members 120a.

As described above, since the filling members 120a and the surface member 120b are formed at a same time, they may be a single integrated structure. Therefore, the warpage preventing member 120 may be closely adhered to the body 110 without using a separate adhering member. As a result, additional costs required at the time of forming an adhering member may be eliminated, and heat generated at the time of an operation of the semiconductor chip is not blocked by an adhering member, whereby heat dissipation efficiency may be significantly improved.

The warpage preventing member 120 may be formed of a material, for example, a metal or a resin based material having a coefficient of thermal expansion (CTE) that is higher than a CTE of silicon (Si), which is a base material of the body 110. Therefore, the warpage preventing member 120 may be expanded at the time of high-temperature treatment such as reflow or the like, to straighten the body 110, which was warped during grinding to be substantially in parallel to a length direction, thereby reducing the warpage of the body 110.

In addition, in a case in which the warpage preventing member 120 is formed of a metal such as copper (Cu), aluminum (Al), nickel (Ni), or gold (Au) having a Young's modulus greater than a Young's modulus of the body 110, the warpage preventing member 120 serves as a stiffener supporting the body 110 in a direction perpendicular to the surface of the body 110, whereby warpage preventing characteristics may be further improved.

Further, the metal or the resin material of the warpage preventing member 120 may have thermal conductivity that is greater than a thermal conductivity of silicon (Si), which is the base material of the body 110. In this case, the semiconductor chip 100 may exhibit improved heat dissipation characteristics.

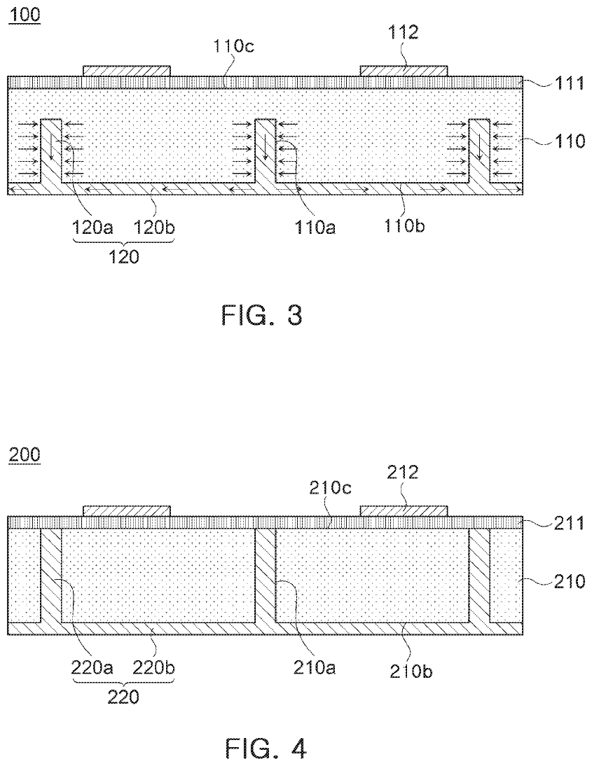

FIG. 3 is a view illustrating a movement path of heat generated in a semiconductor chip according to an embodiment. Referring to FIG. 3, the heat in the semiconductor chip 100 moves toward the filling members 120a, and the heat transferred to the filling members 120a is radiated externally through the surface member 120b which directly contacts air.

As described above, the filling members 120a may have a pillar shape and are inserted into the body 110, such that they serve as paths through which the heat in the semiconductor chip 100 is absorbed and then transferred to the surface member 120b, thereby significantly improving overall heat dissipation characteristics of the semiconductor chip. The heat dissipation characteristics of the semiconductor chip 100 may be further improved when the warpage preventing member 120 is formed of a metal having excellent thermal conductivity.

In a case in which a resin is used as the material of the warpage preventing member 120, a polymer such as epoxy, or the like, having a CTE that is greater than a CTE of the solder resist layer 111 may be used as a resin material.

Since the solder resist layer 111 is generally formed of polyimide having a CTE that is greater than a CTE of the body 110, when the warpage is generated in the body 110, the solder resist layer 111 is expanded in a direction in which the body 110 is warped, such that the warpage of the body 110 is further increased. However, when the warpage preventing member 120 having the CTE greater than the CTE of the solder resist layer 111 is provided, and more specifically, when the surface member 120b of the warpage preventing member 120 is provided on the first surface 110b of the body 110 opposing the second surface 110c of the body 110 on which the solder resist layer 110 is formed, force acts in a direction opposing force applied by the solder resist layer 111 to offset the force applied by the solder resist layer 111. Thus, the generation of warpage in the body 110 is suppressed.

FIG. 4 is a cross-sectional view of a semiconductor chip 200 according to another embodiment. Referring to FIG. 4, in the semiconductor chip 200 may have a rectangular parallelepiped shape and includes a first, lower surface 210b, a second, upper surface 210c opposing the first surface 210b, and holes 210a penetrating entirely through the body 210 and through the first and second surfaces 210b and 210c of the body 210 in a vertical direction.

In addition, a solder resist layer 211 is disposed on any one of the first and second surfaces 210b and 210c of the body 210 that is provided as a mounting surface. Therefore, first ends of the holes 210a are blocked by the solder resist layer 211, and a warpage preventing member 220 is formed by filling a metal or resin based material having a CTE that is greater than a CTE of the body 210 through second ends of the holes 210. That is, the warpage preventing member 220 includes filling members 220a formed in the holes 210a and extending entirely through the body 210, and a surface member 220b formed integrally with the filling members 220a and formed on the first surface 210b of the body 210 opposing the second surface 210c of the body 210 on which the solder resist layer 211 is formed.

As described above, the solder resist layer 211 serves as a shielding layer shielding the first ends of the holes 210a before the warpage preventing member 220 is formed, thereby preventing a material of the warpage preventing member 220 from protruding externally of the body 210, as well as serving as a protecting layer.

The warpage preventing member 220 may be formed of a metal or a resin having thermal conductivity greater than that of silicon (Si), which is a base material of the body 210, similar to the previous embodiment. In a case in which the warpage preventing member 220 is formed of a metal, a metal material having a Young's modulus that is greater than a Young's modulus of the body 210 may be used. In a case in which the warpage preventing member 220 is formed of a resin, a polymer having a CTE that is greater than a CTE of the solder resist layer 211 may be used to further resist a warpage phenomenon.

As set forth above, in the semiconductor chips according to the disclosed embodiments, a warpage preventing member including filling members inserted into holes in a body of the semiconductor chip, and a surface member formed integrally with the filling members, is provided in the body, whereby a warpage phenomenon of the semiconductor chip may be significantly decreased.

In addition, the heat in the semiconductor chips may be radiated through the filling members, whereby heat dissipation characteristics of the semiconductor chip may be improved.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor chip comprising:
a body comprising an upper surface and a lower surface;
holes penetrating through the upper surface and the lower surface;
a solder resist layer disposed on the upper surface or the lower surface; and
a warpage preventing member comprising filling members disposed in the holes, and a surface member disposed on one of the upper surface and the lower surface opposing the other of the upper surface and the lower surface on which the solder resist layer is disposed.

2. The semiconductor chip of claim 1, wherein the filling members and the surface member are formed as a single integrated structure.

3. The semiconductor chip of claim 1, wherein the warpage preventing member has a coefficient of thermal expansion that is greater than a thermal coefficient of expansion of the body.

4. The semiconductor chip of claim 1, wherein the warpage preventing member has thermal conductivity that is greater than a thermal conductivity of the body.

5. The semiconductor chip of claim 1, wherein the warpage preventing member is formed of a metal or a resin.

6. The semiconductor chip of claim 5, wherein the warpage preventing member is formed of the metal and has a Young's modulus that is greater than a Young's modulus of the body.

7. The semiconductor chip of claim 5, wherein the warpage preventing member is formed of the resin and has a coefficient of thermal expansion that is greater than a thermal coefficient of expansion of the solder resist layer.

8. The semiconductor chip of claim 1, wherein each of the holes and each of the filling members extend entirely through the body.
